(19) United States
(12) Patent Application Publication
(10) Pub. No.: US 2018/0358571 A1
(43) Pub. Date: Dec. 13, 2018

(54) PEROVSKITE-BASED SOLAR CELL USING GRAPHENE AS CONDUCTIVE TRANSPARENT ELECTRODE

(71) Applicants: Global Frontier Center for Multiscale Energy Syste, Seoul (KR); Seoul National University R&DB Foundation, Seoul (KR)

(72) Inventors: Man Soo CHOI, Seoul (KR); Hyangki SUNG, Seoul (KR); Namyoung AHN, Seoul (KR); Jong-Kwon LEE, Seoul (KR); Min Seok JANG, Seoul (KR)

(21) Appl. No.: 15/745,225

(22) PCT Filed: Jun. 23, 2016
(86) PCT No.: PCT/KR2016/006710

§ 371 Date: Jan. 16, 2018

(30) Foreign Application Priority Data
Jun. 25, 2015 (KR) 10-2015-0090139
Oct. 27, 2015 (KR) 10-2015-0149135
May 30, 2016 (KR) 10-2016-0066251

(51) Int. Cl. H01L 51/44; H01L 51/42; H01L 51/00; H01L 31/0224

(52) U.S. Cl. CPC H01L 51/442; H01L 51/4213; H01L 31/022466; H01L 31/022425; H01L 51/0032

(57) ABSTRACT

The present invention relates to a perovskite-based solar cell using graphene as a material for a transparent conductive electrode. The perovskite-based solar cell achieves a maximum conversion efficiency of ≥17% through an appropriate combination of energy bands of a graphene electrode, a hole transport layer, a perovskite, an electron transport layer, and a metal electrode.

### BACKGROUND OF THE INVENTION

### 1. Field of the Invention

The present invention relates to an energy device, including a solar cell, and more specifically to a solar cell using a flexible graphene electrode as a substitute for existing transparent conducting oxide electrodes, such as brittle ITO and FTO electrodes, and a perovskite as an absorber.

### 2. Description of the Related Art

Organic/inorganic hybrid perovskites are promising materials for photoactive layers of solar cells due to their high absorption coefficients, balanced electron/hole mobility, low-temperature processability, small exciton binding energy, and longer exciton diffusion lengths than organic semiconductor materials. High-performance perovskite solar cells generally employ an n-i-p architecture consisting of a metal oxide, such as TiO₂ or Al₂O₃, a perovskite, and a hole transport material. However, the production of metal oxide thin films requires high-temperature processing at least 450° C., limiting the choice of substrates. This limitation causes an increase in production cost.

Organic materials as alternatives to metal oxides have also been utilized in p-i-n architecture perovskite solar cells as well as general n-i-p architecture solar cells. Solution processable poly(3,4-ethylenedioxythiophene):poly(styrene sulfonate) (PEDOT:PSS) and [6,6]-phenyl C61-butyric acid methyl ester (PCBM) have been typically used as materials for hole transport layers (HTLs) and electron transport layers (ETLs), respectively. In recent years, p-i-n devices including indium tin oxide (ITO)/PEDOT:PSS/CH₃NH₃PbI₃ (MAPbI₃)/PCBM/gold (Au) have achieved an 18.1% power conversion efficiency. However, this value is still lower than those (≥20%) of recent n-i-p devices using metal oxide scaffolds as materials for electron transport layers (ETLs). Nevertheless, p-i-n perovskite solar cells are being extensively investigated due to their low hysteresis behavior, low processing temperature, and ease of fabrication.

p-i-n architecture perovskite-based solar cells based on low-temperature processing use ITO-coated polyethylene naphthalate (PEN) films as electrodes. Such perovskite-based solar cells were reported to show a maximum efficiency of 12.2% but lose their efficiency by repeated bending, which was reported to be attributed to the mechanical brittleness of ITO layers. On the other hand, in the field of organic photovoltaics (OPVs), extensive research has already been made on flexible conductive electrode materials, such as graphene, carbon nanotubes, metal grids, and conductive polymers that are applicable to flexible solar cells and can substitute for brittle transparent conducting oxides (TCOs). Of these, the most promising candidates are graphene and monolayer 2D carbon materials that are optically very transparent (whose transmittance in the visible region is about 97%), are mechanically robust, and have flexibility and elasticity. The use of graphene as material for transparent conductive electrodes of dye-sensitized solar cells or organic solar cells is known in the prior art. A tandem polymer solar cell using a graphene transparent electrode was reported to achieve a maximum efficiency of 8.48%. However, the tandem structure consisting of a large number of constituent layers causes troublesome problems during processing. The PCE efficiency of the tandem polymer solar cell is still lower than those (11.0%) of TCO-free perovskite solar cells. Recent research efforts have focused on developing perovskite devices using graphene electrodes. However, the graphene electrodes are not used as substitutes for conventional TCO electrodes but are merely used as top electrodes.

The fabrication of solar cells on flexible substrates has recently received attention as a major area of development for next-generation solar cell technology. Stable operation of flexible solar cells requires the use of less brittle materials for the constituent layers of the solar cells. Transparent conducting oxides, such as indium tin oxide (ITO) and fluorine doped tin oxide (FTO), are widely used for transparent conductive electrodes of solar cells. However, high brittleness of the transparent conducting oxides is a cause of low efficiency of the solar cells when the solar cells are repeatedly bent.

Graphene has low conductivity but is readily available compared to transparent conducting oxides. Graphene is excellent in transmittance, mechanical strength, and flexibility. Due to these advantages, graphene is expected to be an alternative material for flexible transparent electrodes.

Organometallic halide perovskites have brought about a considerable increase in the efficiency (≥20%) of third-generation solar cells due to their high absorbance and charge mobility. Even about 500 nm thin films of organometallic halide perovskites are suitable for use in flexible solar cells.

### SUMMARY OF THE INVENTION

The present invention has been made in an effort to overcome the above-mentioned drawbacks of the prior art and it is an object of the present invention to provide a solar cell using a flexible graphene electrode as a substitute for existing transparent conducting oxide electrodes (such as brittle ITO and FTO electrodes) and a perovskite as an absorber, and a method for fabricating the solar cell.

One aspect of the present invention provides a perovskite-based solar cell including a graphene layer as a transparent conductive electrode.

The transparent conductive electrode may be a transparent front electrode.

The solar cell may have a structure in which a transparent anode composed of the graphene layer, a hole transport layer, a perovskite layer, an electron transport layer, and a cathode are laminated in this order on a substrate.

Alternatively, the solar cell may have a structure in which a transparent cathode composed of the graphene layer, an electron transport layer, a perovskite layer, a hole electron transport layer, and an anode are laminated in this order on a substrate.

The solar cell may further include a metal oxide layer deposited on the transparent anode or cathode composed of the graphene layer.

The metal oxide layer may include at least one metal oxide selected from the group consisting of MoO₃, NiO, CoO, and TiO₂.

The metal oxide layer may have a thickness of about 0.5 nm to about 6 nm.

The perovskite may be prepared using a lead halide adduct.

The lead halide adduct may be a compound represented by Formula 1:

A.PbY2.Q (1)

wherein A is an organic or inorganic halide, Y is F⁻, Cl⁻, Br⁻ or I⁻ as a halogen ion, and Q is a Lewis base including a functional group containing an atom with an unshared pair of electrons as an electron pair donor, the FT-IR peak of the functional group in the compound of Formula 1 being red-shifted by 1 to 10 cm⁻¹ relative to that in a compound represented by Formula 2:

PbY₂. Q (2)

wherein Y and Q are as defined in Formula 1.

A in Formula 1 may be CH₃NH₃I, CH(NH₂)₂I or CsI.

The perovskite may be prepared by heating and drying the adduct to remove the Lewis base from the adduct.

### Advantageous Effects

The present inventors have succeeded in developing a perovskite-based solar cell using graphene as a material for a transparent conductive electrode and achieving a maximum efficiency of 17.1% through an appropriate combination of energy bands of a graphene electrode, a hole transport layer, a perovskite, an electron transport layer, and a metal electrode. This maximum efficiency is the highest among those of graphene electrode-based solar cells reported thus far and is higher than those of solar cells using transparent conductive electrodes (e.g., metal thin films or electrodes made of conductive organic materials, such as PEDOT:PSS) other than graphene electrodes, as replacements for transparent conducting oxide electrodes, such as ITO or FTO electrodes. In addition, the solar cell of the present invention is highly efficient and flexible on a polymer substrate, such as a graphene-coated PET or PEN substrate, and is expected to undergo less reduction in efficiency even when repeatedly bent, unlike existing solar cells using ITO electrodes. Furthermore, the solar cell of the present invention is expected to be useful for the development of flexible perovskite-based photoelectronic devices (e.g., photosensors and light-emitting diodes) and perovskite-based memory devices.

### BRIEF DESCRIPTION OF THE DRAWINGS

FIG. 1 shows the power conversion efficiency (PCE) of a perovskite-based solar cell using a graphene electrode as a transparent conductive electrode according to the present invention.

FIG. 2 is a schematic diagram of a perovskite-based solar cell using a graphene electrode as a transparent conductive electrode.

FIG. 3 shows PEDOT:PSS droplets on (a) graphene, (b) 1 nm MoO₃-deposited graphene, (c) 2 nm MoO₃-deposited graphene, (d) ITO, (e) UVO-treated ITO, and (f) UVO-treated ITO covered with 1 nm MoO₃.

FIG. 4 shows SEM images of (a) graphene (b) graphene/1 nm MoO₃, and (c) graphene/2 nm MoO₃ (scale bar 100 nm).

FIG. 5 shows cross-sectional SEM images of (a) a device having a graphene/2 nm MoO₃ electrode and (b) a device having an ITO/1 nm MoO₃ electrode, which were measured in SE (left) and BSE modes (right).

FIG. 6 shows the relationships between the average PCE values and the thicknesses of MoO₃ on (a) a graphene electrode and (b) an ITO electrode of the devices, J-V curves of the best-performing devices of (c) Example 2 and (d) Comparative Example 2, (e) the relationships between the sheet resistance values of graphene and ITO and the thicknesses of MoO₃, and (f) the transmittance values of graphene and ITO with or without a 2 nm-thick MoO₃ layer.

FIG. 7 shows J-V curves of devices fabricated in (a) Example 1 and (b) Example 2.

FIG. 8 shows a PCE histogram of devices fabricated in Example 2 and Comparative Example 2.

FIG. 9 shows EQE spectra (black lines) and J_{sc} (blue lines) of best-performing devices fabricated in Example 2 and Comparative Example 2.

FIG. 10 shows transmittance values of glass/graphene and glass/ITO with or without a 2 nm-thick MoO₃ layer.

FIG. 11 shows UPS spectra and calculated work functions of (a) ITO and (b) graphene with different thicknesses of MoO₃ layers and (c) schematic energy levels of constituent layers.

FIG. 12 shows AFM images (3 μm×3 μm) of (a) graphene, (b) Example 2), (c) Example 2/PEDOT:PSS, (d) Comparative Example 1, (e) Comparative Example 2, and (f) Comparative Example 2/PEDOT:PSS.

FIG. 13 shows plan-view SEM images of MAPbI₃ perovskite films fabricated on (a) Example 2/PEDOT:PSS and Comparative Example 2/PEDOT:PSS, and (c) and (d) higher magnification images of (a) and (b), respectively.

FIG. 14 shows (a) FT-IR spectra of DMSO (solution), PbI₂. DMSO (powder), and MAI.PbI₂.DMSO (powder), and (b) compares FT-IR spectra of MAI PbI₂.DMSO (powder) and FAI.PbI₂.DMSO (powder).

FIG. 15 shows FT-IR spectra of PbI₂. TU (powder) and FAI. PbI₂. TU (powder).

### DETAILED DESCRIPTION OF THE INVENTION

As the present invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, detailed explanations of related art are omitted when it is deemed that they may unnecessarily obscure the essence of the present invention.

The present invention will now be described in detail.

The present invention provides a perovskite-based solar cell including a graphene layer as a transparent conductive electrode.

According to a preferred embodiment, the transparent conductive electrode may be a transparent front electrode.

The solar cell may have a structure in which a transparent anode composed of the graphene layer, a hole transport layer, a perovskite layer, an electron transport layer, and a cathode are laminated in this order on a substrate.

Alternatively, the solar cell may have a structure in which a transparent cathode composed of the graphene layer, an electron transport layer, a perovskite layer, a hole electron transport layer, and an anode are laminated in this order on a substrate.

According to one embodiment of the present invention, the solar cell may have a structure in which a transparent anode, a hole injecting layer (a metal oxide layer), a hole transport layer, a perovskite layer, an electron transport layer, and a cathode are laminated in this order on a substrate.

Graphene, a two-dimensional carbon allotrope, can be produced by various methods, such as exfoliation, chemical oxidation/reduction, thermolysis, and chemical vapor deposition. The exfoliation refers to a method in which a single layer of graphene is physically separated from graphite, the chemical oxidation/reduction refers to a method in which graphite is dispersed in a solution and is chemically reduced to obtain graphene, and the thermolysis refers to a method in which a silicon carbide (SiC) substrate is thermally decomposed at a high temperature to obtain a graphene layer. Particularly, an exemplary method for synthesizing high-quality graphene is chemical vapor deposition. The method for producing graphene is not limited but chemical deposition is preferred. Monolayer graphene was used in the Examples section that follows but is not limited thereto. For example, multilayer graphene may also be used.

The graphene layer may have a thickness of 0.01 to 35 nm, preferably 0.01 to 3.5 nm, more preferably 0.01 to 0.35 nm.

According to one embodiment, the graphene may have an aspect ratio of 0.1 or less, consist of 100 layers or less, and have a specific surface area of 300 m²/g or more. The graphene refers to a single planar network of sp²-bonded carbon (C) atoms in the hcp crystal structure of graphite. In a broad sense, graphene is intended to include graphene composite layers consisting of a plurality of layers.

No particular restriction is imposed on the method for transferring the graphene to the substrate. Any suitable method known in the art may be used to transfer the graphene to the substrate and its detailed description is thus omitted.

According to the present invention, the electron transport layer may be directly formed on the transparent cathode (graphene layer) or the hole transport layer may be directly formed on the transparent anode (graphene layer). A metal oxide layer may be optionally deposited on the graphene layer. The metal oxide layer may act as a hole injecting layer on the graphene layer (transparent anode). Alternatively, the metal oxide layer may act as an electron injecting layer on the graphene layer (transparent cathode).

According to one embodiment, the metal oxide layer may be deposited to allow the graphene layer to have wettability. The metal oxide layer may include at least one metal oxide selected from the group consisting of MoO₃, NiO, CoO, and TiO₂. However, any suitable material known in the art may be used without limitation as a material for the metal oxide layer.

The metal oxide layer may have a thickness of about 0.5 nm to about 6 nm, preferably about 1 nm to about 6 nm, more preferably about 1 nm to about 4 nm, even more preferably about 2 nm to about 3 nm.

The hole transport layer may be composed of a material selected from the group consisting of: poly(3,4-ethylenedioxythiophene)polystyrene sulfonate (PEDOT:PSS); tetrafluoro-tetracyano-quinodimethane (CuPc: F₄-TCNQ); and blends of PEDOT:PSS and one or more materials selected from the group consisting of tungsten oxide (WOₓ), graphene oxide (GO), carbon nanotubes (CNTs), molybdenum oxide (MoOₓ), vanadium oxide (V₂O₅), and nickel oxide (NiOₓ). However, suitable materials known in the art may be used without limitation to form the hole transport layer. For example, the hole transport layer may include a hole transport monomer or polymer. The hole transport monomer may be 2,2′,7,7′-tetrakis(N,N-di-p-methoxyphenylamine)-9,9′-spirobifluorene (spiro-MeOTAD) and the hole transport polymer may be poly(3-hexylthiophene) (P3HT). The hole transport layer may include a doping material. The doping material may be selected from the group consisting of, but not limited to, Li-based dopants, Co-based dopants, and combinations thereof. For example, the hole transport layer may be formed using a mixture of spiro-MeOTAD, 4-tert-butylpyridine (tBP), and Li-TFSI.

In a preferred embodiment of the present invention, PEDOT:PSS as a material for the hole transport layer is a conductive polymer in which a polystyrene sulfonate (PSS) gel and poly(3,4-ethylenedioxythiophene) (PEDOT), a polymer containing 5 to 10 thiophene units, are dispersed in an aqueous solution. The electron transport layer may include one or more materials selected from the group consisting of fullerenes, bathocuproine (BCP), and fullerene derivatives, and one or more metal oxides selected from the group consisting of TiO₂, ZnO, SrTiO₃, and WO₃. However, suitable materials known in the art may be used without limitation to form the electron transport layer.

A non-limiting example for fullerene derivatives is phenyl-C61-butyric acid methyl ester (PCBM). According to a preferred embodiment, C60/BCP as a fullerene derivative may be used. The cathode or the anode may be used as a front or rear electrode. Each of the electrodes may be made of at least one metal selected from the group consisting of, but not limited to, Pt, Au, Al, Ni, Cu, Ag, In, Ru, Pd, Rh, Ir, Os, C, and combinations. However, any suitable material known in the art may be used without limitation as a material for the electrode.

According to a further embodiment of the present invention, the perovskite may be prepared using a lead halide adduct.

The lead halide adduct may be a compound represented by Formula 1:

A.PbY2.Q (1)

wherein A is an organic or inorganic halide, Y is F⁻, Cl⁻, Br⁻ or I⁻ as a halogen ion, and Q is a Lewis base including a functional group containing an atom with an unshared pair of electrons as an electron pair donor, the FT-IR peak of the functional group in the compound of Formula 1 being red-shifted by 1 to 10 cm⁻¹ relative to that in a compound represented by Formula 2:

PbY₂. Q (2)

wherein Y and Q are as defined in Formula 1.

A in Formula 1 may be CH₃NH₃I, CH(NH₂)₂I or CsI.

The perovskite may be prepared by heating and drying the adduct to remove the Lewis base from the adduct.

The preparation of perovskites using the adduct can be found in Korean Patent Application Nos. 2015-0090139 and 2015-0164744, which were filed by the present applicants and are incorporated herein by reference in their entirety.

According to one embodiment, A in Formula 1 may be an organic or inorganic halide in which an organic cation represented by Formula 3:

(R₁R₂N═CH—NR₃R₄)⁺ (3)

wherein R₁, R₂, R₃, and R₄ are independently selected from hydrogen and substituted or unsubstituted C₁-C₆ alkyl, an organic cation represented by Formula 4:

(R₈R₆R₇R₈N)⁺ (4)

wherein R₅, R₆, R₇, and R₈ are independently hydrogen, substituted or unsubstituted C₁-C₂₀ alkyl or substituted or unsubstituted aryl, or a Cs⁺ cation is bonded to a halogen ion selected from F⁻, Cl⁻, Br⁻, and I⁻.

More specifically, A in Formula 1 may be selected from methylammonium iodide (CH₃NH₃I, MAI), formamidinium iodide (CH(NH₂)₂I, FAI), and CsI.

Q in Formula 1 is a Lewis base including a functional group containing a nitrogen (N), oxygen (O) or sulfur (S) atom as an electron pair donor. More specifically, Q in Formula 1 may be a Lewis base including at least one functional group selected from the group consisting of thioamide, thiocyanate, thioether, thioketone, thiol, thiophene, thiourea, thiosulfate, thioacetamide, carbonyl, aldehyde, carboxyl, ether, ester, sulfonyl, sulfo, sulfinyl, thiocyanate, pyrrolidone, peroxy, amide, amine, imide, imine, azide, pyridine, pyrrole, nitro, nitroso, cyano, nitroxy, and isocyano groups, each of which has a nitrogen, oxygen or sulfur atom as an electron pair donor. A compound including at least one functional group selected from the group consisting of thioamide, thiocyanate, thioether, thioketone, thiol, thiophene, thiourea, thioacetamide, and thiosulfate groups, each of which has a sulfur (S) atom as an electron pair donor, is more preferred because of its ability to form a strong bond with the lead halide.

For example, Q in Formula 1 may be selected from the group consisting of dimethyl sulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine, and n-propylamine. Preferably, Q in Formula 1 is selected from thiourea (TU), N,N-dimethylthioacetamide (DMTA), and thioacetamide (TAM), each of which includes a sulfur (S) atom as an electron pair donor.

The FT-IR peak corresponding to the functional group containing the electron pair donating atom where the Lewis base represented by Q is bonded to Pb is red-shifted by 10 to 30 cm⁻¹ relative to that in the compound of Formula 2.

The Lewis base may be in the form of a liquid and is preferably non-volatile or only slightly volatile. The Lewis base may have a boiling point of 120° C. or above, for example 150° C. or above.

The present invention also provides a method for preparing the lead halide adduct represented by Formula 1. Specifically, the method includes: dissolving a lead halide, an organic or inorganic halide, and a Lewis base including a nitrogen (N), oxygen (O) or sulfur (S) atom as an electron pair donor in a first solvent to prepare a precursor solution; and adding a second solvent to the precursor solution and collecting the resulting precipitate by filtration.

The lead halide, the halide including a divalent cation, and the organic material including a ligand may be mixed in a molar ratio of 1:1:1-1.5, most preferably 1:1:1.

According to one embodiment, the first solvent may be a solvent that can dissolve the lead halide, the organic or inorganic halide, and the organic material including a functional group containing a nitrogen (N), oxygen (O) or sulfur (S) atom as an electron pair donor, and may be selected from the group consisting of propanediol-1,2-carbonate (PDC), ethylene carbonate (EC), diethylene glycol, propylene carbonate (PC), hexamethylphosphoric triamide (HMPA), ethyl acetate, nitrobenzene, formamide, γ-butyrolactone (GBL), benzyl alcohol, N-methyl-2-pyrrolidone (NMP), acetophenone, ethylene glycol, trifluorophosphate, benzonitrile (BN), valeronitrile (VN), acetonitrile (AN), 3-methoxypropionitrile (MPN), dimethyl sulfoxide (DMSO), dimethyl sulfate, aniline, N-methylformamide (NMF), phenol, 1,2-dichlorobenzene, tri-n-butyl phosphate, o-dichlorobenzene, selenium oxychloride, ethylene sulfate, benzenethiol, dimethylacetamide, diethylacetamide, N,N-dimethylethanamide (DMEA), 3-methoxypropionitrile (MPN), diglyme, cyclohexanol, bromobenzene, cyclohexanone, anisole, diethylformamide (DEF), dimethylformamide (DMF), 1-hexanethiol, hydrogen peroxide, bromoform, ethyl chloroacetate, 1-dodecanethiol, di-n-butyl ether, dibutyl ether, acetic anhydride, m-xylene, p-xylene, chlorobenzene, morpholine, diisopropyl ethylamine, diethyl carbonate (DEC), 1-pentanediol, n-butyl acetate, 1-hexadecanethiol, and mixtures thereof.

The first solvent may be added in an excessive amount for complete dissolution. Preferably, the first solvent is added in such an amount that the weight ratio of the lead halide to the first solvent is 1:1-3.

According to one embodiment, the second solvent may be a nonpolar or weakly polar solvent that is capable of selectively removing the first solvent. For example, the second solvent may be selected from the group consisting of acetone-based solvents, C₁-C₃ alcohol-based solvents, ethyl acetate-based solvents, diethyl ether-based solvents, alkylene chloride-based solvents, cyclic ether-based solvents, and mixtures thereof.

According to one embodiment, the use of toluene and chlorobenzene as general volatile solvents for the preparation of the perovskite from the lead halide adduct may lead to low reproducibility because the quality of the perovskite is greatly influenced by the amounts of the solvents dripped and/or the spinning rate of a cleaning solution and the difference in solubility between the spinning solution and the precursor solution. In contrast, the addition of a sufficient amount of the second solvent, preferably a diethyl ether-based solvent, to the first solvent irrespective of spin coating conditions ensures high reliability of the perovskite film.

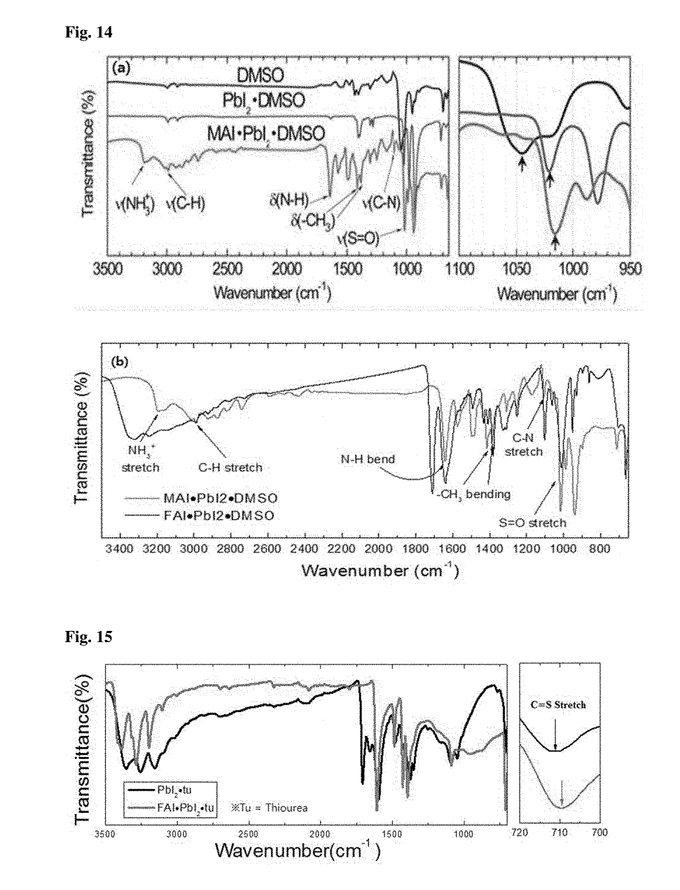

According to a preferred embodiment of the present invention, the adduct may include XRD diffraction peaks at 20 angles of 7-8.5 and 9.8-10.5, specifically at 20 angles of 6-7, 7-8.5, and 9.8-10.5 or at 20 angles of 7-8.5, 9.8-10.5, 11-12.5, and 13-14 (see FIGS. 14 and 15). These peaks are not found in compounds prepared by other methods and are characteristic to the adduct.

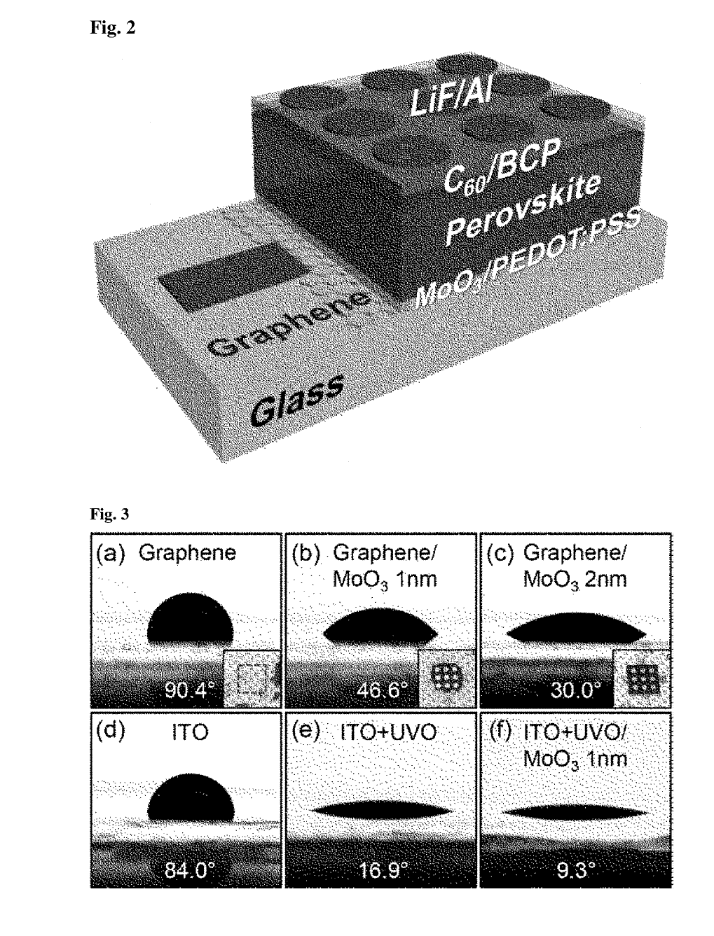

According to one embodiment, the lead halide adduct may form the transparent thin film shown in FIG. 2.

The lead halide adduct in the form of a thin film may be heated to a temperature of 30° C. or above, preferably 40° C. or above or 50° C. or above. For example, the lead halide adduct may be heated to the temperature range of 30° C. to 150° C. to form the desired perovskite. The heating may be performed at a temperature of 30° C. to 80° C. and subsequently at a temperature of 90° C. to 150° C. This stepwise heating allows the perovskite crystal to have a dense structure. The annealing process enables the removal of the organic ligand organic material corresponding to Q in Formula 1 from the crystal structure of the lead halide adduct, leading to the formation of the perovskite. According to one embodiment, the resulting perovskite thin film may have a dark color, such as dark brown.

The substrate may be a flexible substrate made of a polymer or a non-flexible substrate made of glass.

According to a preferred embodiment, a highly efficient TCO-free perovskite-based solar cell is provided which includes graphene as a material for the transparent anode, molybdenum trioxide (MoO₃) as a material for the metal oxide layer, PEDOT:PSS as a material for the hole transport layer, methylammonium lead iodide (MAPbI₃) as a material for the perovskite layer, and lithium fluoride (LiF)/aluminum (Al) as a material for the cathode. The present invention will be explained in more detail with reference to its preferred embodiments. However, it should be understood that these embodiments are not intended to limit the scope of the present invention and various modification can be made thereto.

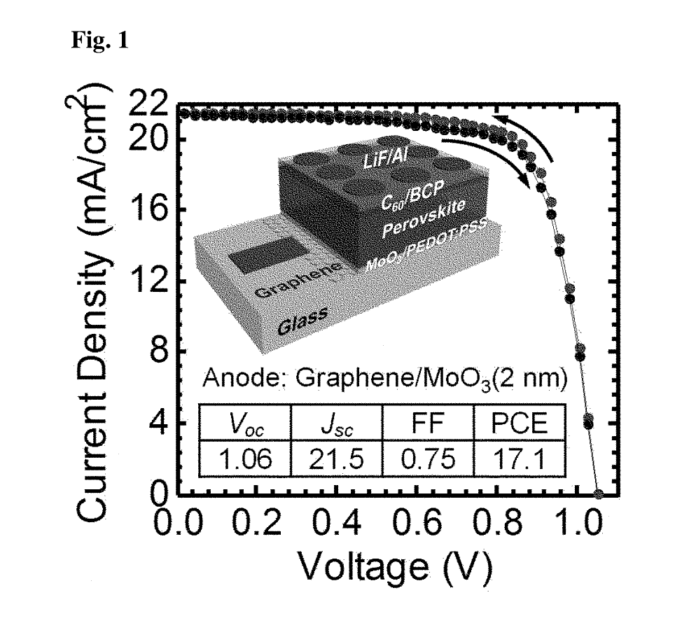

The MoO₃ layer has a thickness of several nanometers and is formed between the graphene layer and the PEDOT:PSS layer. The MoO₃ layer imparts hydrophilicity to the graphene surface and can increase its work function (4.23 eV) to a higher level (4.71 eV) through hole doping. The wettability and device physical properties of the PEDOT:PSS are affected by the thickness of the MoO₃ layer. According to a preferred embodiment, the introduction of the MoO₃ interfacial layer having a thickness of about 2 mm may achieve a conversion efficiency of about 17.1% (see FIG. 1).

The structure of a MAPbI₃ perovskite-based solar cell device according to one embodiment of the present invention is schematically illustrated in FIG. 2. The solar cell uses graphene, PEDOT:PSS, and C60/BCP as materials for a transparent conductive electrode, a hole transport layer (HTL), and an electron transport layer (ETL), respectively. The structure is processable at low temperature, thus being suitable for next-generation devices on flexible plastic substrates.

The use of monolayer graphene grown by chemical vapor deposition (CVD) leads to an increase in work function (˜4.3 eV) by p-type doping, resulting in an improvement in the conductivity, and induces the energy level of the highest occupied molecular orbital (HOMO) of a hole transport layer (e.g., ˜5.2 eV for PEDOT:PSS) to a preferred level. Accordingly, monolayer graphene is preferred used as a material for a transparent anode. However, the use of monolayer graphene is not limited to a transparent anode. For example, graphene may be used as a cathode material after n-type doping, if needed. In the present invention, a MoO₃ layer is deposited between the graphene layer and the PEDOT:PSS layer by thermal evaporation, followed by annealing at 150° C. on a hot plate to prevent possible loss during subsequent spin coating. The interfacial properties of the graphene electrode, such as the wettability and doping level of the PEDOT:PSS layer, are controlled by varying the thickness of the MoO₃ layer in the range of 0 to 4 nm. The wettability of the PEDOT:PSS on the graphene is a very important factor in the performance of the device.

The perovskite-based solar cell using graphene as a transparent conductive electrode material according to the present invention will be more specifically explained with reference to the following examples, including experimental examples. However, these examples are merely illustrative and should not be construed as limiting the scope of the invention.

### <Examples 1-3> Fabrication of Graphene-Based Perovskite-Based Solar Cells

Graphene was grown on a copper foil by CVD and transferred to a pre-cleaned glass substrate (AMG, 25×25 mm²) to prepare monolayer graphene-coated glass. Graphene-based perovskite-based solar cells were fabricated using the graphene-coated glass (Graphene Square Inc. >1 kΩcm², 15×15 mm²).

Ultrathin MoO₃ layers having different thicknesses of 1 nm, 2 nm, and 4 nm were formed on the monolayer graphene-coated glass substrate by thermal evaporation at a deposition rate of 0.1 Ås⁻¹, followed by annealing at 150° C. for 10 min. The deposition rate and the thicknesses were monitored using a quartz crystal sensor. The hydrophobic surface of the graphene was changed to hydrophilic by the MoO₃ layers.

Thereafter, the substrate was wetted with deionized water, spin coated with 50 μl of a PEDOT:PSS solution (Clevios P VP Al 4083) at 5000 rpm for 30 sec, and annealed at 150° C. for 20 min to form a hole transport layer.

A perovskite layer was formed as an absorber on the hole transport layer. The perovskite layer was formed by the following procedure. First, MAI, Pb₂, and DMSO were mixed in a molar ratio of 1:1:1. The mixture was completely dissolved in a 50 wt % DMF solution without heating. The hole transport layer was spin coated with 50 μl of the MAI.PbI₂. DMSO solution at 3500 rpm for 20 sec. 8 sec after initiation of the spin coating, 0.3 ml of diethyl ether (DE) was slowly dropped onto the coating to remove the excess dimethylformamide, leaving a CH₃NH₃I.PbI₂. DMSO adduct film. The adduct film was sequentially annealed at 65° C. for 1 min and at 100° C. for 4 min to form the perovskite layer in the form of a dark-brown film.

Thereafter, the resulting structure was sequentially deposited with C₆₀ (20 nm), BCP (10 nm), LiF (0.5 nm), and Al (150 nm) in a thermal evaporator at <10⁻⁶ torr. All spin coating processes were carried out under ambient conditions.

### <Comparative Examples 1-4> Fabrication of ITO-Based Perovskite-Based Solar Cells

ITO-based perovskite-based solar cells were fabricated on commercial ITO-coated glass substrates (AMG, 9.5 Ωcm², 25×25 mm²).

The ITO-coated glass substrates were cleaned with acetone, isopropanol, and deionized water (each for 15 min) in an ultrasonic bath, dried with nitrogen gas, and stored in an oven at 120° C. before use.

Ultrathin MoO₃ layers having different thicknesses of 1 nm, 2 nm, and 4 nm were formed on the washed and dried ITO-coated glass substrates by thermal evaporation at a deposition rate of 0.1 As⁻¹, followed by annealing at 150° C. for 10 min. The deposition rate and the thicknesses were monitored using a quartz crystal sensor.

Thereafter, the substrate was wetted with deionized water, spin coated with 50 μl of a PEDOT:PSS solution at 5000 rpm for 30 sec, and annealed at 150° C. for 20 min to form a hole transport layer.

A perovskite layer was formed as an absorber on the hole transport layer. The perovskite layer was formed by the following procedure. First, MAI, Pb₂, and DMSO were mixed in a molar ratio of 1:1:1. The mixture was completely dissolved in a 50 wt % DMF solution without heating. The hole transport layer was spin coated with 50 μl of the MAI.PbI₂.DMSO solution at 3500 rpm for 20 sec. 8 sec after initiation of the spin coating, 0.3 ml of diethyl ether (DE) was slowly dropped onto the coating to remove the excess dimethylformamide, leaving a CH₃NH₃I.PbI₂.DMSO adduct film. The adduct film was sequentially annealed at 65° C. for 1 min and at 100° C. for 4 min to form the perovskite layer in the form of a dark-brown film.

Thereafter, the resulting structure was sequentially deposited with C₆₀ (20 nm), BCP (10 nm), LiF (0.5 nm), and Al (150 nm) in a thermal evaporator at <10⁻⁶ torr. All spin coating processes were carried out under ambient conditions.

### <Experimental Example 1> Characterization of the Solar Cells

The SEM images, J-V curves, external quantum efficiency (EQE) spectra, sheet resistance values, transmittance values, UPS spectra, and AFM images of the perovskite-based solar cells of Examples 1-3 and Comparative Examples 1-4 were analyzed by the following procedures.

SEM images were analyzed using a field emission scanning electron microscope (AURIGA, Zeiss). Sunlight simulation was performed under AM 1.5G 1 sun illumination conditions using an Oriel Sol3A solar simulator whose light intensity was calibrated to give 100 mWcm⁻² using a standard Si photovoltaic cell (RC-1000-TC-KG5-N, VLSI Standards)

J-V curves were recorded using a Keithley 2400 source meter. The forward and reverse scan rates were set to 200 ms per 20 mV and the active area of each device was 1.77 mm².

EQE spectra were measured using a Newport IQE200 system with a 300 mW xenon light source and a lock-in amplifier.

Sheet resistance was measured using a 4-point probe (CMT-SERIES, Advanced Instrument Technology).

Transmittance was measured by UV-vis spectroscopy (Cary 5000, Agilent).

UPS was measured using a helium discharge lamp (He I 21.2 eV, AXIS-NOVA, Kratos) and AFM images were obtained using a scanning probe microscope (XE-100, Park Systems) in a non-contact mode.

Improvement in the Wettability of the PEDOT:PSS and the Hydrophilicity of the Graphene Electrode by the Deposited MoO₃ Layers

The wettability of the PEDOT:PSS of the graphene-based devices and the ITO-based devices is very important in the performance of the devices. The difference in the wettability of the PEDOT:PSS with and without MoO₃ was analyzed by contact angle measurement.

FIG. 3 shows optical microscopy images of the PEDOT:PSS droplets dropped onto the graphene and ITO surfaces. As shown in FIG. 3a, the contact angle of the graphene surface for the PEDOT:PSS without MoO₃ was measured to be 90.4±0.3°, and as a result, it appears that subsequent PEDOT:PSS/MAPbI₃ layers are difficult to form by spin coating (see the inset in FIG. 3a). As shown in FIGS. 3b and 3c, however, the contact angle of the 1 nm-thick MoO₃ layer on the graphene for the PEDOT:PSS was 46.6±1.3° and the contact angle of the 2 nm-thick MoO₃ layer on the graphene for the PEDOT:PSS was 30.0±1.6°. The insets in FIGS. 3b and 3c show that the presence of the MoO₃ layers improved the wettability of the PEDOT:PSS together with decreased contact angles.

As shown in FIG. 3c, the dark brown MAPbI₃ film was in the form of a quadrangle in the central portion of the glass substrate of the MoO₃ layer, which had previously been thermally evaporated. Particularly, the well-defined quadrangular MAPbI₃ film was formed on the 2 nm-thick MoO₃ layer and the PEDOT:PSS showed better wettability on the thicker MoO₃ layer.

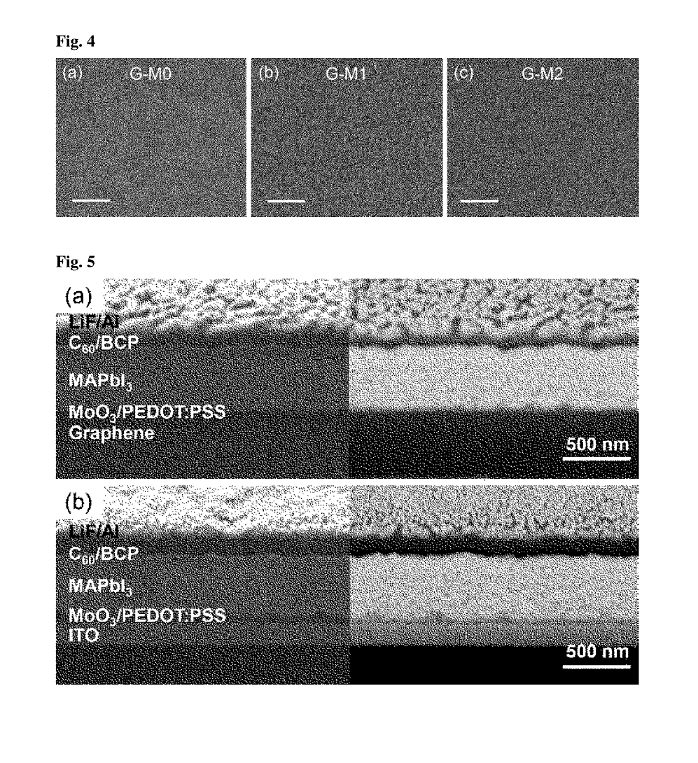

The SEM images of FIG. 4 clearly show incomplete covering of the 1 nm-thick MoO₃ layer over the hydrophobic graphene surface and complete covering with the 2 nm-thick MoO₃ layer over the hydrophobic graphene surface.

For comparison, the contact angles of the ITO surface for the PEDOT:PSS were measured before and after a combination of UV/ozone (UVO) treatment and MoO₃ deposition, as shown in FIGS. 3d-3f. As a result, similarly to graphene, the ITO surface showed no wettability on the PEDOT:PSS, which forms subsequent films by spin coating. The contact angle of the ITO surface was significantly reduced from 84.0±1.3° (FIG. 3d) to 16.9±1.80 (FIG. 3e) after UVO treatment. The contact angle was slightly reduced to 9.3±0.6° (FIG. 3f) by the 1 nm-thick MoO₃ layer, indicating improved wettability of the ITO surface.

FIG. 5 shows cross-sectional SEM images of the device using the 2 nm-thick MoO₃/graphene electrode (FIG. 5a) and the device using the 1 nm-thick MoO₃/ITO electrode (FIG. 5b). The left and right images of FIG. 5 were measured in secondary electron (SE) and back-scattered electron modes (BSE), respectively. The hydrophobicity of the PEDOT:PSS layers formed on the graphene and the ITO with similar thicknesses (˜50 nm) and morphologies by spin coating was maintained stable and continuous by the MoO₃ interfacial layers. As shown in FIG. 5, the perovskite films of the graphene-based device and the ITO-based device were observed to have uniform thicknesses (˜510 nm) and very smooth surfaces.

Each of the smooth and dense perovskite films was formed using a Lewis base adduct of PbI₂. The present inventors have recently succeeded in developing a highly reproducible n-i-p perovskite solar cell with a maximum conversion efficiency of 19.7% using the Lewis base adduct. The method for fabricating the perovskite solar cell can be found in Korean Patent Application No. 2015-0164744. The MAI PbI₂.DMSO adduct film was formed by spin coating while dropwise addition of diethyl ether (DE) for removing an excess of methylformamide (DMF) by washing and was then converted into the perovskite film by annealing.

Influence of the MoO₃ Layer Thicknesses on the Performance of the Devices

To investigate the influence of the MoO₃ layer thicknesses on the performance of the devices, the perovskite solar cells of Examples 1-3 and Comparative Examples 1-4 using the MoO₃ layers with different thicknesses on the graphene electrodes and the ITO electrodes were measured for open-circuit voltage (V_{oc}), short-circuit current density (J_{sc}), fill factor (FF), power conversion efficiency (PCE), and highest conversion efficiency. The results are shown in Table 1.

TABLE 1

| | | MoO₃ | | | | | Highest |
|---|---|---|---|---|---|---|---|
| | | thickness | V_{oc} | J_{sc} | | PCE | PCE |
| | Electrode | [nm] | [V] | [mAcm²] | FF | [%] | [%] |
| Example 1 | Graphene | 1 | 0.72 ± 0.36 | 17.6 ± 6.3 | 0.45 ± 0.09 | 6.7 ± 4.2 | 12.1 |
| (G-M1) | | | | | | | |
| Example 2 | | 2 | 1.03 ± 0.02 | 21.9 ± 0.4 | 0.72 ± 0.02 | 16.1 ± 0.6 | 17.1 |
| (G-M2) | | | | | | | |
| Example 3 | | 4 | 1.00 ± 0.01 | 22.9 ± 0.4 | 0.70 ± 0.02 | 15.9 ± 0.5 | 16.2 |
| (G-M4) | | | | | | | |
| Comparative | ITO | 0 | 0.96 ± 0.01 | 21.4 ± 0.5 | 0.83 ± 0.02 | 17.0 ± 0.4 | 17.6 |
| Example 1 | | | | | | | |
| (ITO-M0) | | | | | | | |
| Comparative | | 1 | 0.97 ± 0.01 | 22.6 ± 0.4 | 0.83 ± 0.01 | 18.2 ± 0.5 | 18.8 |
| Example 2 | | | | | | | |
| (ITO-M1) | | | | | | | |
| Comparative | | 2 | 0.95 ± 0.01 | 22.2 ± 0.4 | 0.76 ± 0.01 | 16.1 ± 0.4 | 16.9 |
| Example 3 | | | | | | | |
| (ITO-M2) | | | | | | | |
| Comparative | | 4 | 0.94 ± 0.01 | 21.0 ± 0.4 | 0.74 ± 0.01 | 14.7 ± 0.6 | 15.7 |
| Example 4 | | | | | | | |
| (ITO-M4) | | | | | | | |

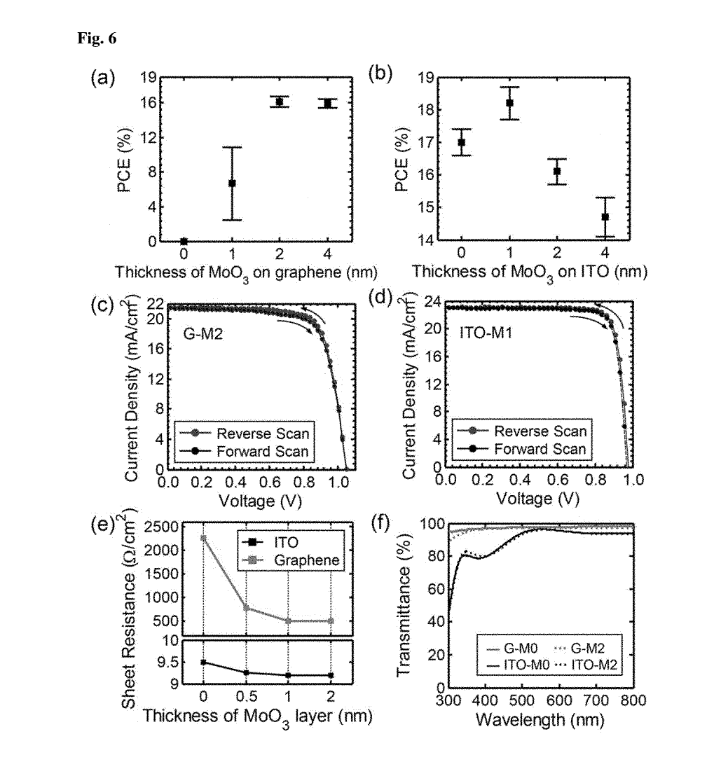

The relationships between the average PCE values and the MoO₃ layer thicknesses are shown in FIGS. 6a and 6b.

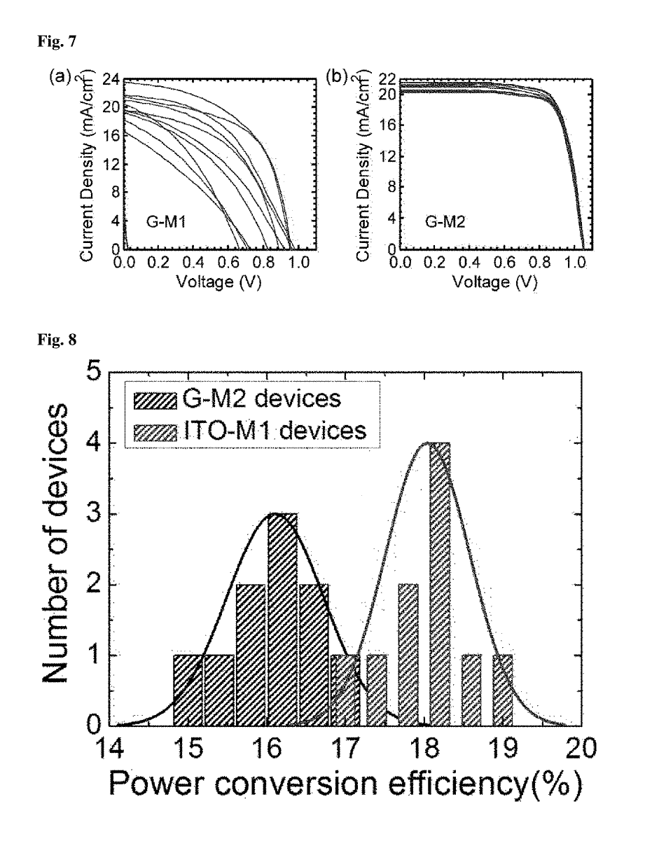

As shown in FIG. 6, since the hydrophobic graphene surface of the graphene-based device without MoO₃ was not wetted, a PEDOT:PSS solution or a perovskite solution failed to form a film after spin coating, making it impossible to evaluate the PCE of the device (see the inset in FIG. 3a). In the device with the 1 nm-thick MoO₃ layer (Example 1), non-uniform PEDOT:PSS coating caused a considerable PCE change in the range of 0-12.1%. This result demonstrates incomplete covering of the 1 nm-thick MoO₃ layer over the hydrophobic graphene surface. As a consequence, the current density and voltage (J-V) characteristics of the device were not maintained constant (FIG. 7a).

In contrast, the average PCE values of the devices of Examples 2 and 3 having the >1 nm thicker MoO₃ layers were 16.1% and 15.9%, respectively, and the performance deviation between the devices was significantly reduced (FIGS. 6a and 7b). Particularly, the device of Example 2 achieved a maximum PCE of 17.1%, which is the best result obtained in perovskite-based solar cells using graphene electrodes instead of general TCO electrodes and corresponds to the highest conversion efficiency ever achieved in TCO-free solar cells.

As shown in FIG. 6b, the PCE values of the ITO-based devices of Comparative Examples 1-4 were greatly affected by the change in the thickness of MoO₃. The average PCE (18.2%) of the device of Comparative Example 2 was higher than that (17.0%) of the device of Comparative Example 1. The average PCE values of the devices of Comparative Examples 3 and 4 having the >1 nm MoO₃ layers were lowered to 16.1% and 14.7%, respectively.

FIG. 8 shows a PCE histogram of the devices of Example 2 and Comparative Example 2 for each electrode type.

The J-V curves of the best-performing devices of Example 2 and Comparative Example 2 under AM 1.5G, 1 sun illumination (100 mW cm²), which were measured through reverse and forward bias sweeps, are shown in FIGS. 6c and 6d, respectively. The devices of Example 2 and Comparative Example 2 showed no significant hysteresis in the scanning directions.

The device of Example 2 was found to have a higher series resistance and a lower shunt resistance than the device of Example 2. To understand the electric properties of the MoO₃-modified graphene and ITO electrodes, the sheet resistance values were measured using a four-point probe. FIG. 6e shows the relationships between the sheet resistance of the graphene and the ITO and the thicknesses of the MoO₃ layers. As shown in this figure, the initial high sheet resistance (>2 kΩcm²) of the graphene was significantly reduced to ˜780 Ωcm² by the deposition of the 0.5 nm-thick MoO₃ layer and was further reduced to ˜500 Ωcm² when the MoO₃ layer thickness was increased to 2 nm. The initial sheet resistance of the ITO was measured to be 9.5 Ωcm² and was slightly reduced to 9.2 Ωcm² by the deposition of the 1 and 2 nm-thick MoO₃ layers. The initial sheet resistance of the monolayer graphene was significantly reduced by doping with a 4-fold larger amount of MoO₃ but the reduced sheet resistance was still even higher than the sheet resistance of the ITO. This explains a higher series resistance, a lower shunt resistance, and a lower fill factor (FF) of the device of Example 2 than the device of Comparative Example 2.

Transparency of the Devices

As shown in FIG. 6f, single-atom thick monolayer graphene showed high transparency (˜97% transmittance) in the visible region compared to ITO (˜89% transmittance) and the device of Example 2 showed a short-circuit current density (J_{sc}) comparable to the device of Comparative Example 2.

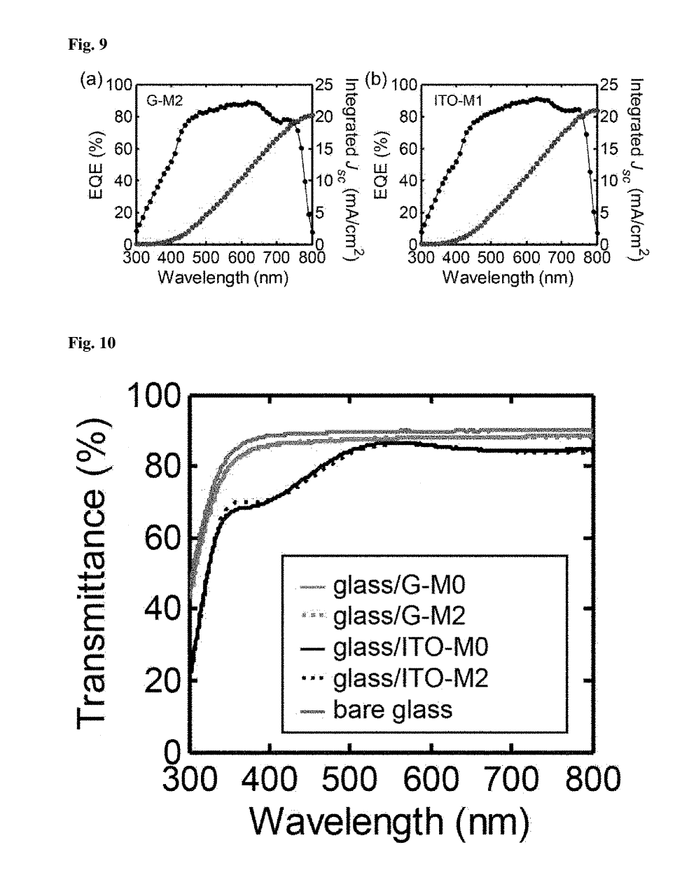

FIG. 9 shows external quantum efficiency (EQE) spectra of the devices of Example 2 and Comparative Example 2. The integrated photocurrents of the devices were calculated at 20.2 and 21.0 mA cm⁻¹, respectively. Since the higher transmittance of the graphene anode than the ITO anode compensate for the lower carrier collection efficiency of the graphene anode, the EQE of the graphene-based device was similar to that of the ITO-based device (FIGS. 6f and 9). Although the conductivity of graphene is even lower than that of ITO, the device of Example 2 showed a high open-circuit voltage (V_{oc}) compared to the device of Comparative Example 2. This result contributes to a higher PCE of the device of Example 2 (by ≥90% than the device of Comparative Example 2).

Difference in Work Function Between the Devices

Despite the same structure of the devices, the difference in the V_{oc} of the devices using different electrodes is associated with the difference in the work function of the electrodes. Ultraviolet photoelectron spectroscopy (UPS) was used to investigate the effect of the ultrathin MoO₃ layers on the work functions of the ITO and graphene electrodes.

FIG. 11 shows UPS spectra of the ITO and graphene electrodes depending on different thicknesses of the MoO₃ layers. As shown in FIG. 11, the deposition of the 0.5 nm-thick MoO₃ layer caused a rapid shift to a high kinetic energy of the ITO due to the ability of the MoO₃ to block secondary electrons. The evidence for this was an increase in work function from 4.29 eV to 4.65 eV. Further deposition of the MoO₃ layer to thicknesses of 1 nm and 2 nm increased the work function to 4.69 eV and 4.72 eV, respectively. Thus, for efficient hole-collection, it is preferred to minimize the energy barrier between the anode and the hole transport layer (HTL). As shown in Table 1, the higher J_{sc} and PCE of the device of Comparative Example 2 than the device of Comparative Example 1 are attributed to an increase in the work function of the central electrode inducing improved hole-collection efficiency. On the other hand, the PCE of the device decreased with increasing thickness of the MoO₃ layer to 2 nm and 4 nm. The thin MoO₃ layer acts like an insulating layer between the ITO and the organic semiconductor in the device structure. Holes can pass through the MoO₃ layer based on the tunneling effect, a gradual reduction of a film having a thickness larger than ˜3 nm. There is a possibility that the hole collection efficiencies of the devices of Comparative Examples 3 and 4 may lead to an increase in the work function of the electrodes but a sudden reduction in the FF and PCE of the devices of Comparative Examples 3 and 4 may also lead to a decrease in the tunneling probability of holes compared to the device of Comparative Example 2.

The UPS spectra of the graphene-based devices showed a behavior similar to those of the ITO-based devices deposited with the MoO₃ layer. As shown in FIG. 11b, a rapid change of photoelectron initiation in the 0.5 nm-thick MoO₃ layer deposited on the graphene led to an increase in work function from 4.23 eV to 4.61 eV. Further deposition of the MoO₃ layer to thicknesses of 1 nm and 2 nm increased the work function to 4.67 eV and 4.71 eV, respectively. As shown in FIG. 11c, the ultrathin MoO₃ layer deposited on the graphene promoted the collection of holes from the hole transport layer to the graphene anode and enabled successful spin coating of the PEDOT:PSS film on the hydrophobic graphene surface due to the decreased energy barrier at the interface.

Comparison of the UPS data of the ITO and graphene electrodes revealed that the work functions were almost the same at the same thickness of the MoO₃ layers. The work function of the device of Comparative Example 2 was not greatly different from that of the device of Example 2. This means that the higher V_{oc} of the device of Example 2 than the device of Comparative Example 2 is not explained in terms of different energy barriers at the anode/HTL interfaces.

V_{oc} is also affected by the interfacial quality. For this reason, the morphologies of the electrodes after formation of the MoO₃ and PEDOT:PSS films were observed by atomic force microscopy (AFM).

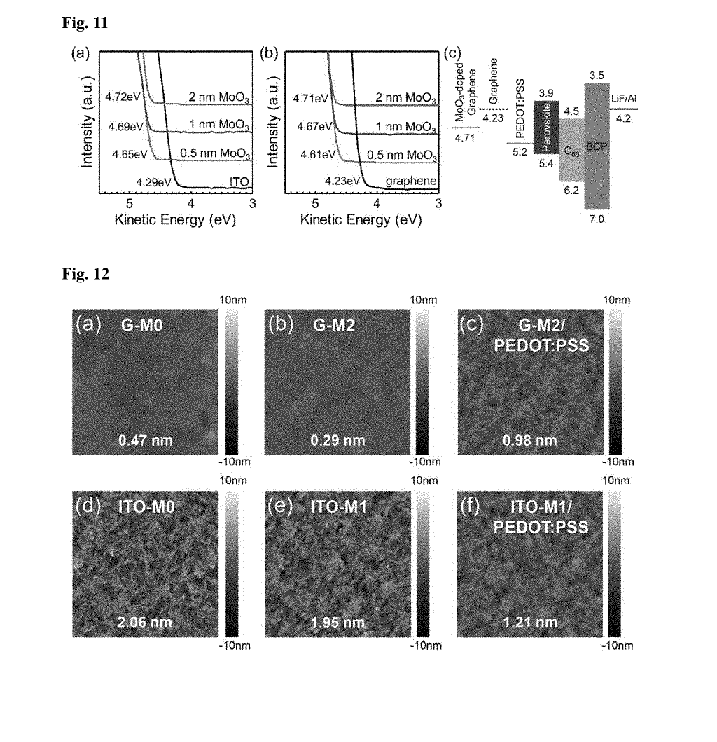

As shown in FIGS. 12a-12f, the root-mean-square (rms) roughness values of the ITO (Comparative Example 1), the ITO-1 nm MoO₃ (Comparative Example 2), and the ITO-1 nm MoO₃ (Comparative Example 2)/PEDOT:PSS were 2.06, 1.95, and 1.2, respectively. The root-mean-square (rms) roughness of the graphene-2 nm MoO₃ (Example 2) was 0.29 nm, which was 6-fold lower than that (1.95 nm) of the ITO-1 nm MoO₃ (Comparative Example 2). Here, the ITO-1 nm MoO₃ (Comparative Example 2)/PEDOT:PSS means the presence of the PEDOT:PSS layer in addition to the MoO₃ layer having the same thickness as the ITO-1 nm MoO₃ (Comparative Example 2). The graphene-2 nm MoO₃ (Example 2)/PEDOT:PSS can also be interpreted as having the same meaning as the ITO-1 nm MoO₃ (Comparative Example 2)/PEDOT:PSS.

It is generally known that when an increase in V_{oc} is achieved using an underlying layer whose surface roughness is smaller than that of an overlying layer, a better interface can be formed between the layers. In this connection, the electrode contributing to the high V_{oc} of the device of Example 2 appears to establish a better interface of PEDOT:PSS than the ITO-1 nm MoO₃ (Comparative Example 2)/PEDOT:PSS interface.

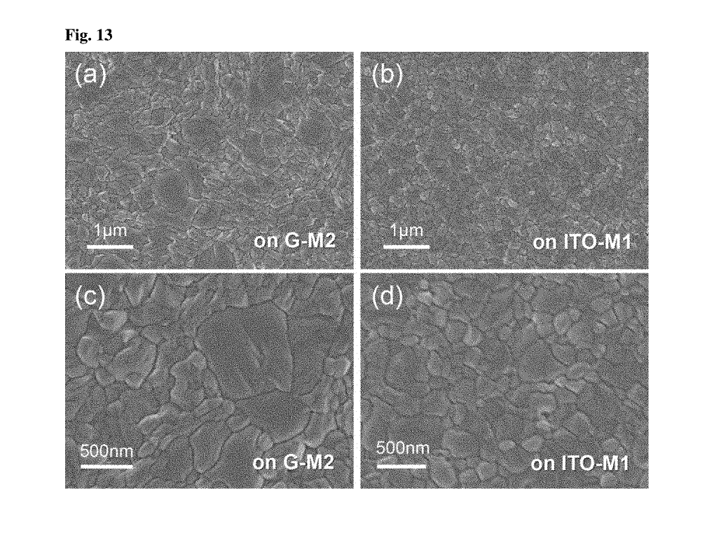

Furthermore, the SEM images of the surfaces of the perovskite on the graphene-2 nm MoO₃ (Example 2)/PEDOT:PSS and the ITO-1 nm MoO₃ (Comparative Example 2)/PEDOT:PSS (FIGS. 12 and 13) show that the grain size of the perovskite on the graphene-2 nm MoO₃ (Example 2)/PEDOT:PSS was larger than that of the perovskite in the ITO-1 nm MoO₃ (Comparative Example 2)/PEDOT:PSS.

Since the nano-scale edges of the surface can function as nucleation sites, the surface roughness of the underlying layer plays an important role in determining the grain size of the PEDOT:PSS. Therefore, the particles of the perovskite film on the smooth surface of the graphene-2 nm MoO₃ (Example 2)/PEDOT:PSS can grow to a larger size than the particles on the surface of the ITO-1 nm MoO₃ (Comparative Example 2)/PEDOT:PSS. The larger particles of the graphene-2 nm MoO₃ (Example 2) reduced voltage loss resulting from the recombination of charges at the grain boundaries. Therefore, surface roughness is given as a factor that provides a higher V_{oc} to the device of Example 2 than to the device of Comparative Example 2.

The TCO-free solar cell of the present invention uses graphene as a material for the transparent conductive anode and has high efficiency. The introduction of the MoO₃ layer on the surface of the anode leads to the formation of a better interface and enables a favorable alignment of energy levels between the anode and the hole transport layer. Particularly, the deposition of the MoO₃ on the graphene allows the graphene to play a better role as the conductive electrode. The graphene-based device and the ITO-based device achieved the highest PCE values of 17.1% and 18.8%, respectively, at the optimum thicknesses of the MoO₃ layer. In comparison with the ITO electrode, the graphene electrode has a low conductivity but has a similar J_{sc}, a high V_{oc}, a high transparency, and a low surface roughness.

1. A perovskite-based solar cell comprising a graphene layer as a transparent conductive electrode.

2. The solar cell according to claim 1, wherein the transparent conductive electrode is a transparent front electrode.

3. The solar cell according to claim 1, wherein the solar cell has a structure in which a transparent anode composed of the graphene layer, a hole transport layer, a perovskite layer, an electron transport layer, and a cathode are laminated in this order on a substrate.

4. The solar cell according to claim 1, wherein the solar cell has a structure in which a transparent cathode composed of the graphene layer, an electron transport layer, a perovskite layer, a hole electron transport layer, and an anode are laminated in this order on a substrate.

5. The solar cell according to claim 3, further comprises a metal oxide layer deposited on the transparent anode or cathode composed of the graphene layer.

6. The solar cell according to claim 5, wherein the metal oxide layer comprises at least one metal oxide selected from the group consisting of MoO₃, NiO, CoO, and TiO₂.

7. The solar cell according to claim 5, wherein the metal oxide layer has a thickness of about 0.5 nm to about 6 nm.

8. The solar cell according to claim 1, wherein the perovskite is prepared using a lead halide adduct.

9. The solar cell according to claim 8, wherein the lead halide adduct is a compound represented by Formula 1:
A.PbY₂.Q (1)
wherein A is an organic or inorganic halide, Y is F⁻, Cl⁻, Br⁻ or I⁻ as a halogen ion, and Q is a Lewis base comprising a functional group containing an atom with an unshared pair of electrons as an electron pair donor, the FT-IR peak of the functional group in the compound of Formula 1 being red-shifted by 1 to 10 cm⁻¹ relative to that in a compound represented by Formula 2:
PbY₂.Q (2)
wherein Y and Q are as defined in Formula 1.

10. The solar cell according to claim 9, wherein A in Formula 1 is CH₃NH₃I, CH(NH₂)₂I or CsI.

11. The solar cell according to claim 9, wherein the perovskite is prepared by heating and drying the adduct to remove the Lewis base from the adduct.

12. The solar cell according to claim 4, further comprises a metal oxide layer deposited on the transparent anode or cathode composed of the graphene layer.
